(19) United States
(12) Patent Application Publication
(10) Pub. No.: US 2019/0013180 A1
(43) Pub. Date: Jan. 10, 2019

(54) PLASMA TREATMENT APPARATUS

(71) Applicant: SAMSUNG ELECTRONICS CO., LTD., Suwon-Si (KR)

(72) Inventors: SANG CHUL HAN, Suwon-Si (KR); Tae Ki Hong, Suwon-Si (KR)

(21) Appl. No.: 15/870,354

(22) Filed: Jan. 12, 2018

(30) Foreign Application Priority Data
Jul. 5, 2017 (KR) 10-2017-0085544

(51) Int. Cl. H01J 37/32

(52) U.S. Cl. CPC H01J 37/3222; H01J 2237/002; H01J 37/32522

(57) ABSTRACT

A plasma treatment apparatus, includes a plasma chamber configured to perform a plasma treatment. An upper plate is disposed in an upper part of the plasma chamber. A lower plate is disposed under the upper plate. An antenna is disposed between the upper plate and the lower plate. At least a first portion of the antenna is separated from the upper plate and at least a second portion of the antenna is separated from the lower plate. A coolant path is formed in the antenna, and an inner surface of the coolant path includes a same material as an outer surface of the antenna.

### CROSS-REFERENCE TO RELATED APPLICATIONS

This application claims the benefit of Korean Patent Application No. 10-2017-0085544, filed on Jul. 5, 2017, in the Korean Intellectual Property Office, the disclosure of which is incorporated by reference herein in its entirety.

### TECHNICAL FIELD

The present inventive concept relates to a plasma treatment apparatus, and more particularly, to a plasma treatment apparatus which generates an electric field for plasma generation by using an antenna.

### DISCUSSION OF THE RELATED ART

A system for accelerating a desired chemical reaction (e.g., film deposition, etching, etc.) by using plasma is widely utilized in the semiconductor manufacturing industry.

An antenna generates an electric field and creates plasma by exciting a supplied gas using the generated electric field. For uniform electric field generation, the operating condition of the antenna may be maintained.

### SUMMARY

A plasma treatment apparatus includes a plasma chamber configured to perform plasma treatment. An upper plate is disposed in an upper part of the plasma chamber. An antenna is disposed under the upper plate. A lower plate is disposed under the antenna. A first metal ring is attached to a first surface of the antenna and separates at least a portion of the first surface of the antenna from the upper plate. A second metal ring is attached to a second surface of the antenna and separates at least a portion of the second surface of the antenna from the lower plate. A a coolant path, that is configured to pass coolant therethrough, is formed in the antenna.

A plasma treatment apparatus, includes a plasma chamber configured to perform a plasma treatment. An upper plate is disposed in an upper part of the plasma chamber. A lower plate is disposed under the upper plate. An antenna is disposed between the upper plate and the lower plate. At least a first portion of the antenna is separated from the upper plate and at least a second portion of the antenna is separated from the lower plate. A coolant path is formed in the antenna, and an inner surface of the coolant path includes a same material as an outer surface of the antenna.

A plasma treatment apparatus includes a plasma chamber configured to perform plasma treatment. An upper plate is disposed in an upper part of the plasma chamber. A lower plate is disposed under the upper plate. An antenna is disposed between the upper plate and the lower plate. The antenna includes a first inner circumferential portion defined in a first surface facing the upper plate. The first inner circumference is separated from the upper plate and a first outer circumferential portion surrounding the first inner circumferential portion. A second inner circumferential portion is defined in a second surface facing the lower plate. The second inner circumferential portion is separated from the lower plate and a second outer circumferential portion which surrounds the second inner circumferential portion. A coolant path is formed in the antenna so as not to overlap the first and second outer circumferential portions.

### BRIEF DESCRIPTION OF THE DRAWINGS

These and/or other aspects will become apparent and more readily appreciated from the following description of the embodiments, taken in conjunction with the accompanying drawings in which:

FIG. 1 is a conceptual diagram illustrating a plasma treatment apparatus according to exemplary embodiments of the present invention;

FIG. 2 is an enlarged view illustrating a portion ‘A’ of FIG. 1;

FIG. 3 is a top view illustrating an antenna included in a plasma treatment apparatus according to exemplary embodiments of the present invention;

FIG. 4 is a perspective view illustrating the coupling relationship between an antenna and metal rings in a plasma treatment apparatus according to exemplary embodiments of the present invention;

FIG. 5 is a cross-sectional view illustrating a coolant path formed in an antenna included in a plasma treatment apparatus according to exemplary embodiments exemplary;

FIG. 6 is a conceptual diagram illustrating a plasma treatment apparatus according to exemplary embodiments of the present invention;

FIG. 7 is a conceptual diagram illustrating a plasma treatment apparatus according to exemplary embodiments of the present invention; and

FIG. 8 is a conceptual diagram illustrating a plasma treatment apparatus according to exemplary embodiments of the present invention.

### DETAILED DESCRIPTION

In describing exemplary embodiments of the present disclosure illustrated in the drawings, specific terminology is employed for sake of clarity. However, the present disclosure is not intended to be limited to the specific terminology so selected, and it is to be understood that each specific element includes all technical equivalents which operate in a similar manner.

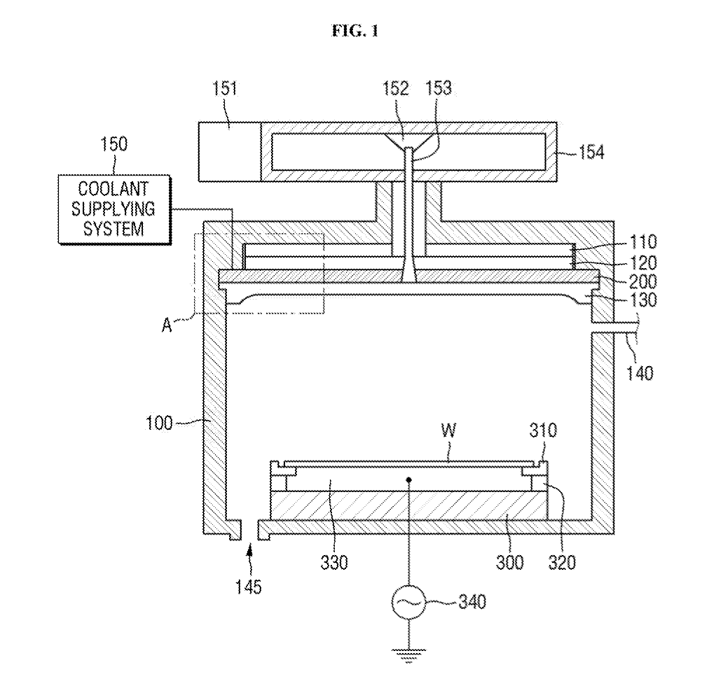

FIG. 1 is a conceptual diagram illustrating a plasma treatment apparatus according to exemplary embodiments of the present invention.

Referring to FIG. 1, the plasma treatment apparatus, according to exemplary embodiments of the present invention, may include a plasma chamber 100, a cooling plate 110, an upper plate 120, a lower plate 130, and an antenna 200.

The plasma chamber 100 may receive a process gas from a gas supply pipe 140 and generate plasma by exciting the process gas. Then, the plasma chamber 100 may treat a wafer W with the generated plasma. The plasma chamber 100 may perform, for example, an etching process, a deposition process, and the like on the wafer W using the generated plasma.

In some exemplary embodiments of the present invention, the plasma chamber 100 may generate microwaves by supplying a current to the antenna 200 and the antenna 200 may emit the generated microwaves to the inside of the plasma chamber 100. In some exemplary embodiments of the present invention, the frequency of the microwaves so-generated and emitted may be about 2.45 GHz.

The plasma chamber 100 may receive a process gas through the gas supply pipe 140 that is connected to a sidewall of the plasma chamber 100. The process gas supplied through the gas supply pipe 140 may include, but is not limited to, fluorocarbon (CₓF_{y}) or oxygen (O₂).

In addition, the plasma chamber 100 may include an outlet 145. Byproducts generated by a plasma treatment process can be discharged through the outlet 145. In FIG. 1, one gas supply pipe 140 and one outlet 145 are illustrated in the plasma chamber 100. However, the inventive concept is not limited to this case, and the plasma chamber 100 can include a plurality of gas supply pipes 140 and a plurality of outlets 145.

The cooling plate 110, the upper plate 120, the lower plate 130, and the antenna 200 may be disposed within the plasma chamber 100. The plates 110, 120 and 130 and the antenna 200 may be disposed above the wafer W and may also be disposed above a lower electrode 330 supporting the wafer W.

The cooling plate 110, the upper plate 120, the lower plate 130 and the antenna 200 may be disposed in an upper part of the plasma chamber 100. A position where the wafer W and the lower electrode 330 supporting the wafer W are disposed within is referred to as a lower part of the plasma chamber 100. A position where the plates 110, 120 and 130 and the antenna 200 are located will be referred to as the upper part of the plasma chamber 100. Within the upper part of the plasma chamber, the plates 110, 120 and 130 and the antenna 200 face the wafer W from across the plasma chamber 100.

The cooling plate 110 may contact the upper plate 120. A first surface of the cooling plate 110 may face an inner wall of the plasma chamber 100, and a second surface of the cooling plate 110 may face the upper plate 120.

The cooling plate 110 may cool the plasma chamber 100. For example, when heat generated from the antenna 200 is transmitted to the upper plate 120, the cooling plate 110 in contact with the upper plate 120 may receive the heat from the upper plate 120, thereby cooling the upper plate 120. Alternatively, heat may be transmitted directly from the plasma chamber 100 to the cooling plate 110, thereby cooling the plasma chamber 100.

The cooling plate 110 may include a flow path, and a coolant may flow along the flow path. The coolant may include, but is not limited to, water or helium (He).

The cooling plate 110 may include a material having high thermal conductivity such as a metal material.

The upper plate 120 may be disposed between the cooling plate 110 and the antenna 200. An upper surface of the upper plate 120 may face the cooling plate 110, and a lower surface of the upper plate 120 may face the antenna 200.

The upper plate 120 may include quartz. However, the material that forms the upper plate 120 is not limited to quartz, and the upper plate 120 can also include a metal material such as alumina. The upper plate 120 may be separated from at least a portion of an upper surface of the antenna 200. Here, the upper surface of the antenna 200 denotes a surface facing the upper plate 120, and a lower surface of the antenna 200 denotes a surface facing the lower plate 130.

In the configuration illustrated in FIG. 1, the cooling plate 110 and the upper plate 120 are separated from each other. However, the inventive concept is not limited to this case. For example, the cooling plate 110 and the upper plate 120 can be integrally coupled to each other, and a coolant flow path can be formed in the resultant plate to cool the plasma chamber 100.

The antenna 200 may be disposed between the upper plate 120 and the lower plate 130. The upper surface of the antenna 200 may be shaped like a circular plate. According to some exemplary embodiments of the present invention, the antenna 200 may include an Invar or Kovar alloy having a relatively low thermal expansion coefficient. Since the antenna 200 includes the Invar or Kovar alloy, the effect of thermal expansion of the antenna 200 can be reduced when the antenna 200 is heated.

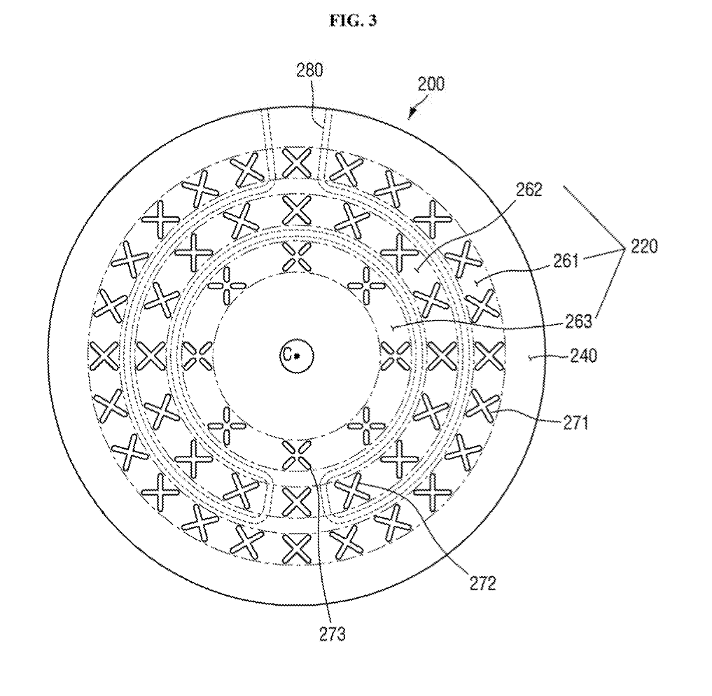

A coolant path 280 (see FIG. 3) may be formed within the antenna 200. A coolant supplying system 150 may cool the antenna 200 by supplying a coolant to the coolant path 280 (see FIG. 3). The coolant may include, but is not limited to, water or helium (He).

The antenna 200 may be connected to a connection part 153 to receive microwaves from a power supply 151. The antenna 200 may include a plurality of slot holes 271 through 273 (see FIG. 3) penetrating its surface, and the microwaves may be emitted from the slot holes 271 through 273.

The lower plate 130 may be disposed under the antenna 200. The lower plate 130 may include, for example, quartz. Microwaves emitted from the antenna 200 pass through the lower plate 130, which may be made of a dielectric, and the microwaves may excite a process gas supplied into the plasma chamber 100. The lower plate 130 may contact at least a portion of the antenna 200.

The power supply 151 generates microwaves. The power supply 151 may be connected to a side of a waveguide 154. Microwaves generated from the power supply 151 may travel along the waveguide 154. The waveguide 154 may have one surface closed.

A converter 152 may be disposed within the waveguide 154. The converter 152 may convert the mode of microwaves generated from the power supply 151. For example, the converter 152 may convert a traverse electric (TE) mode of microwaves generated from the power supply 151 into a traverse electromagnetic (TEM) mode.

The internal conductor 153 may connect the converter 152 and the antenna 200. Microwaves converted by the converter 152 may propagate to the antenna 200 along the internal conductor 153 having one end connected to the converter 152. The other end of the internal conductor 153 may be fixed to a hole formed in the center of the antenna 200.

A focus ring 310 may surround an outer circumferential surface of the wafer W. The focus ring 310 may substantially extend the surface of the wafer W during a plasma treatment process on the wafer W. For example, during the plasma treatment process, the focus ring 310 surrounding the outer circumferential surface of the wafer W may prevent the concentration of plasma at a distal end of the wafer W, e.g., on the outer circumferential surface of the wafer W, by dispersing the plasma. In so doing, the focus ring 310 can prevent a portion of the wafer W from being excessively treated with the plasma.

The lower electrode 330 may be disposed in the plasma chamber 100. The lower electrode 330 may be disposed under the wafer W to support the wafer W. Although not illustrated in FIG. 1, the lower electrode 330 may include an electrostatic chuck in contact with the wafer W.

The lower electrode 330 may be electrically connected to a power supply 340. The power supply 340 may supply power to the lower electrode 330. When power is supplied from the power supply 340 to the lower electrode 330, an electric field map may be formed between the antenna 200 and the lower electrode 330.

In FIG. 1, it is illustrated that one power supply 340 is connected to the lower electrode 330. However, the inventive concept is not limited to this case. Two or more power supplies can be connected to the lower electrode 330, and the two or more power supplies can supply pulse power having different frequencies or duty cycles to the lower electrode 330.

In addition, in FIG. 1, the power supply 340 is illustrated as being directly connected to the lower electrode 330. However, the inventive concept is not limited to this case, and a matching circuit can be connected between the power supply 340 and the lower electrode 330. The matching circuit can minimize reflected power by matching the impedance of an electric circuit formed between the antenna 200 and the lower electrode 330.

A support 300 may support the wafer W and the lower electrode 330. The support 300 may include an insulating material such as ceramic to insulate the lower electrode 330 from the plasma chamber 100.

A support ring 320 may be disposed under the focus ring 310. The support ring 320 may cover a sidewall of the lower electrode 330. The support ring 320 may block plasma from being supplied to the lower electrode 330. The support ring 320 may include a material having etching resistance to a plasma gas and may include, but is not limited to, quartz.

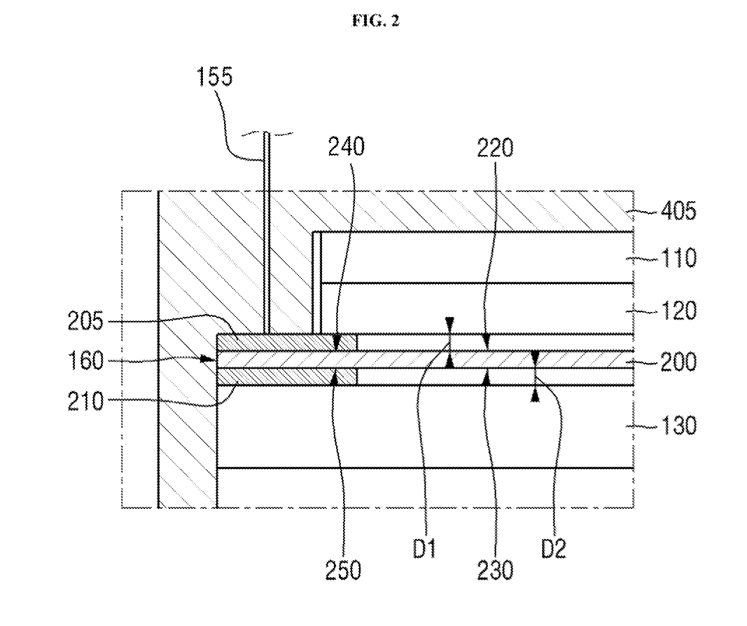

The coupling relationship between the cooling plate 110, the upper plate 120, the lower plate 130, and the antenna 200 will now be described in more detail with reference to FIG. 2.

FIG. 2 is an enlarged view of a portion ‘A’ of FIG. 1.

In FIG. 2, the coupling relationship between the cooling plate 110, the upper plate 120, the lower plate 130, and the antenna 200 is illustrated.

As described above, the cooling plate 110 contacts an upper wall 105 of the plasma chamber 100 and the upper plate 120. A surface of the upper plate 120 contacts the cooling plate 110, and the other surface of the upper plate 120 contacts a first metal ring 205 attached to the antenna 200.

A first surface of the antenna 200, which faces the upper plate 120, includes a first inner circumferential portion 220 disposed on the inner side with respect to a center point and a first outer circumferential portion 240 surrounding the first inner circumferential portion 220. The first inner circumferential portion 220 and the first outer circumferential portion 240 may be concentric circles.

In addition, a second surface of the antenna 200, which faces the lower plate 130, may include a second inner circumferential portion 230 disposed on the inner side with respect to the center point and a second outer circumferential portion 250 surrounding the second inner circumferential portion 230. The second inner circumferential portion 230 and the second outer circumferential portion 250 may be concentric circles.

In some exemplary embodiments of the present invention, the first inner circumferential portion 220 and the second inner circumferential portion 230 may vertically overlap each other. However, the first inner circumferential portion 220 can be broader than the second inner circumferential portion 230 in an outer circumferential direction of the antenna 200 or can be narrower than the second inner circumferential portion 230 in an inner circumferential direction of the antenna 200.

The first metal ring 205 is attached to the first surface of the antenna 200 to contact the upper plate 120. For example, the first metal ring 205 may be attached onto the first outer circumferential portion 240 of the antenna 200 to contact the upper plate 120. For example, the first metal ring 205 at least partially overlaps the first outer circumferential portion 240 of the antenna 200 but does not overlap the first inner circumferential portion 220.

Since the antenna 200 is connected to the upper plate 120 by the first metal ring 205, the first inner circumferential portion 220 may be vertically separated from the upper plate 120. For example, the first inner circumferential portion 220 may be vertically separated from the upper plate 120 by a first distance D1. In some exemplary embodiments of the present invention, the first distance D1 may be equal to a thickness of the first metal rings 205.

In some exemplary embodiments of the present invention, the first distance D1 may be 0.1 mm to 5 mm. If the first distance D1 is smaller than 0.1 mm, the first inner circumferential portion 220 of the antenna 200 and the upper plate 120 may contact each other due to thermal expansion caused by the heating of the antenna 200 resulting from the operation of the antenna 200.

The first metal ring 205 may include a metal material and may include, but is not limited to, the same Invar or Kovar alloy as the antenna 200.

As illustrated in FIG. 2, a coolant may be supplied from the coolant supplying system 150 to the antenna 200 through a coolant supply pipe 155. Therefore, the first metal ring 205 may include a through hole to allow the coolant from the coolant supply pipe 155 to be supplied to the antenna 200.

A second metal ring 210 is attached to the second surface of the antenna 200 to contact the lower plate 130. For example, the second metal ring 210 may be attached onto the second outer circumferential portion 250 of the antenna 200 to contact the lower plate 130. For example, the second metal ring 210 overlaps the second outer circumferential portion 250 of the antenna 200 but does not overlap the second inner circumferential portion 230.

Since the antenna 200 is connected to the lower plate 130 by the second metal ring 210, the second inner circumferential portion 230 may be vertically separated from the lower plate 130. For example, the second inner circumferential portion 230 may be vertically separated from the lower plate 130 by a second distance D2. In some exemplary embodiments of the present invention, the second spacing D2 may be equal to a thickness of the second metal ring 210.

In some exemplary embodiments of the present invention, the second distance D2 may be 0.1 mm to 5 mm. If the second distance D2 is smaller than 0.1 mm, the second inner circumferential portion 230 of the antenna 200 and the lower plate 130 may contact each other due to thermal expansion caused by the heating of the antenna 200 resulting from the operation of the antenna 200.

If the second distance D2 is greater than 5 mm, microwaves emitted from the antenna 200 may be adversely affected. For example, an empty space is interposed between the second inner circumferential portion 230 of the antenna 200 and the lower plate 130 so that these elements are separated from each other. If the microwaves emitted from the antenna 200 travel in the air rather than to the lower plate 130, which is a dielectric, the power of the microwaves may be attenuated.

The second metal ring 210 may include a metal material and may include, but is not limited to, the same Invar or Kovar alloy as the antenna 200.

In some exemplary embodiments of the present invention, the first metal ring 205 and the second metal ring 210 may vertically overlap each other. If the first outer circumferential portion 240 and the second outer circumferential portion 250 of the antenna 200 coincide with each other as described above, the first metal ring 205 and the second metal ring 210 may be vertically aligned with each other.

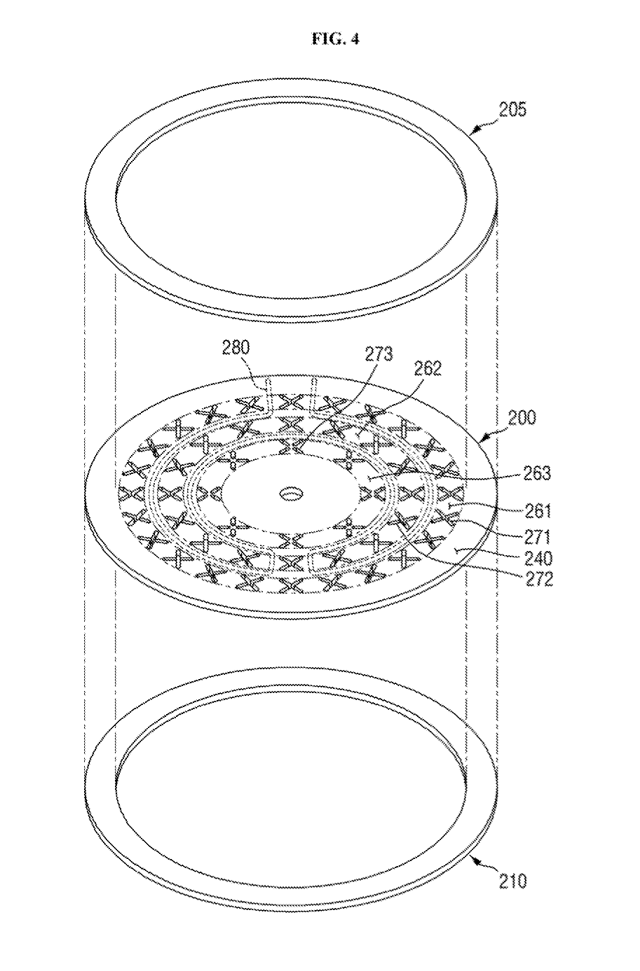

The configuration of the antenna 200 that can be included in a plasma treatment apparatus according to exemplary embodiments of the present invention will now be described in more detail with reference to FIGS. 3 and 4.

FIG. 3 is a top view of an antenna 200 included in a plasma treatment apparatus according to exemplary embodiments of the present invention. FIG. 4 is a perspective view illustrating the coupling relationship between an antenna 200 and metal rings in a plasma treatment apparatus according to exemplary embodiments of the present invention.

Referring to FIGS. 3 and 4, a plurality of slot holes 271 through 273 are formed in a surface of the antenna 200 in which a first inner circumferential portion 220 and a first outer circumferential portion 240 are defined.

The first inner circumferential portion 220 may be divided into first through third areas 261 through 263. Like the first inner circumferential portion 220 and the first outer circumferential portion 240, first through third areas 261 through 263 may be concentric circles having the same center point C. The first area 261 is disposed on the outermost side, and the third area 263 is disposed on the innermost side. Thus, the second area 262 is surrounded by the first area 261. The third area 263 is surrounded by the second area 262 and the first area 261.

The first slot holes 271 may penetrate the antenna 200 in the first area 261. The first slot holes 271 may be disposed in the first area 261 and may be separated from each other in a circumferential direction. As illustrated in FIG. 3, the first slot holes 271 may be X-shaped. However, the shape of the first slot holes 271 is not limited to the X shape, and the first slot holes 271 may alternatively be ‘+’-shaped.

The second slot holes 272 may penetrate the antenna 200 in the second area 262. The second slot holes 272 may be disposed in the second area 262 and may be separated from each other in the circumferential direction. As illustrated in FIG. 3, the second slot holes 272 may be X-shaped. However, the shape of the second slot holes 272 is not limited to the X shape, and the second slot holes 272 may alternatively be ‘+’-shaped.

The third slot holes 273 may penetrate the antenna 200 in the third area 263. The third slot holes 273 may be disposed in the third area 263 to be separated from each other in the circumferential direction. As illustrated in FIG. 3, the third slot holes 273 may be X-shaped. However, the shape of the third slot holes 273 is not limited to the X shape, and the third slot holes 273 may alternatively be ‘+’-shaped.

Since the first through third areas 261 through 263 belong to the first inner circumferential portion 220, they do not overlap the first outer circumferential portion 240. Therefore, the first through third slot holes 271 through 273 formed in the first through third areas 261 through 263 also do not overlap the first outer circumferential portion 240.

Since a first metal ring 205 is attached to the first outer circumferential portion 240, the first through third areas 261 through 263 or the first through third slot holes 273 may also not overlap the first metal ring 205.

As illustrated in FIG. 3, the first area 261 and the second area 262 may be separated from each other in a diameter direction of concentric circles. Therefore, the first slot holes 271 and the second slot holes 272 may also be separated from each other in the diameter direction of the concentric circles. In addition, the second area 262 and the third area 263 may be separated from each other in the diameter direction of the concentric circles, and the second slot holes 272 and the third slot holes 273 may be separated from each other in the diameter direction of the concentric circles.

A coolant path 230 may be formed within the antenna 200. A coolant supplied from the coolant supplying system 150 may be provided to the coolant path 280 through the coolant supply pipe 155. The coolant supplied to the coolant path 280 may cool the antenna 200 to suppress the expansion or deformation of the antenna 200 due to heat.

As illustrated in FIG. 3, the coolant path 280 may pass between the first area 261 and the second area 262 and may pass between the second area 262 and the third area 263. The coolant path 280 might not be formed on the first outer circumferential portion 240 except for an inlet/outlet 281 adjacent to an outer wall of the antenna 200. For example, since heat generation is concentrated in an inner circumference such as the first inner circumferential portion 220 of the antenna 200, cooling may be more needed in the first inner circumferential portion 220 than in the first outer circumferential portion 240. Therefore, the coolant path 280 may pass through the first inner circumferential portion 220 of the antenna 200 without passing through the first outer circumferential portion 240 of the antenna 200.

Although not illustrated in FIG. 3, the coolant path 280 may also be formed inside the third area 263.

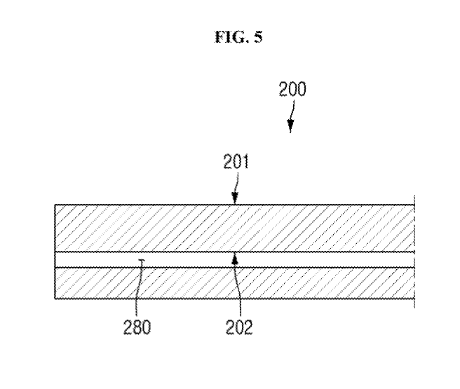

FIG. 5 is a cross-sectional view illustrating a coolant path 280 formed in an antenna 200 included in a plasma treatment apparatus according to exemplary embodiments of the present invention.

Referring to FIG. 5, the coolant path 280 may be formed in the antenna 200. The coolant path 280 may be a groove formed directly in the antenna 200. An inner surface 202 of the coolant path 280 may include the same material as an outer surface 201 of the antenna 200. In some exemplary embodiments of the present invention, the inner surface 202 of the coolant path 280 may include other materials such as an insulator.

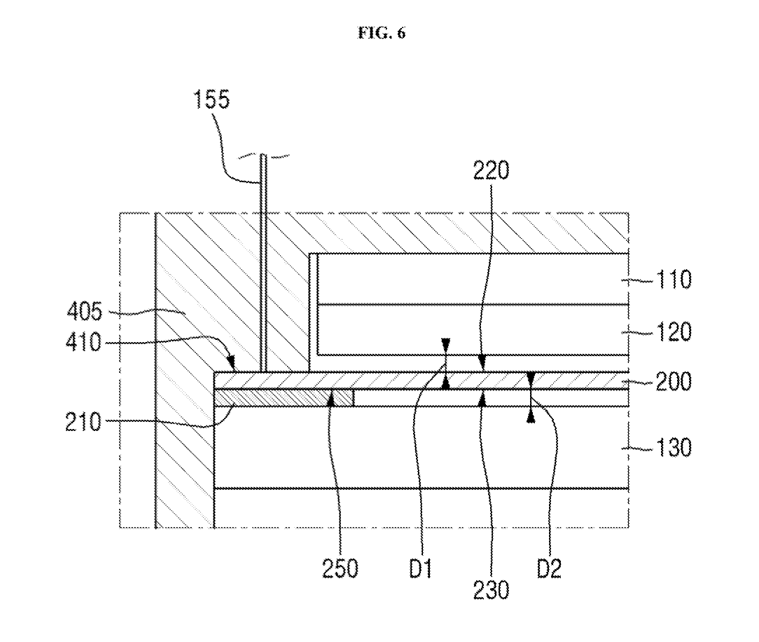

FIG. 6 is a conceptual diagram of a plasma treatment apparatus according to exemplary embodiments of the present invention.

Referring to FIG. 6, the plasma treatment apparatus, according to exemplary embodiments of the present invention, might not include a first metal ring 205 contacting an upper plate 120, unlike in the above-described embodiments.

For example, an antenna 200 may contact a sidewall 405 of a plasma chamber 100 not through the first metal ring 205 but through a step 410 formed on the sidewall 405.

The step 410 formed on the sidewall 405 may be at a different level from the upper plate 120. For example, the step 410 may protrude further down than a surface of the upper plate 120 which faces the antenna 200. Thus, a first inner circumferential portion 220 of the antenna 200 in contact with the step 410 can still be kept separated from the upper plate 120.

A coolant supply pipe 155 may be connected to the antenna 200 directly to supply a coolant thereto, rather than being connected to the antenna 200 by the first metal ring 205.

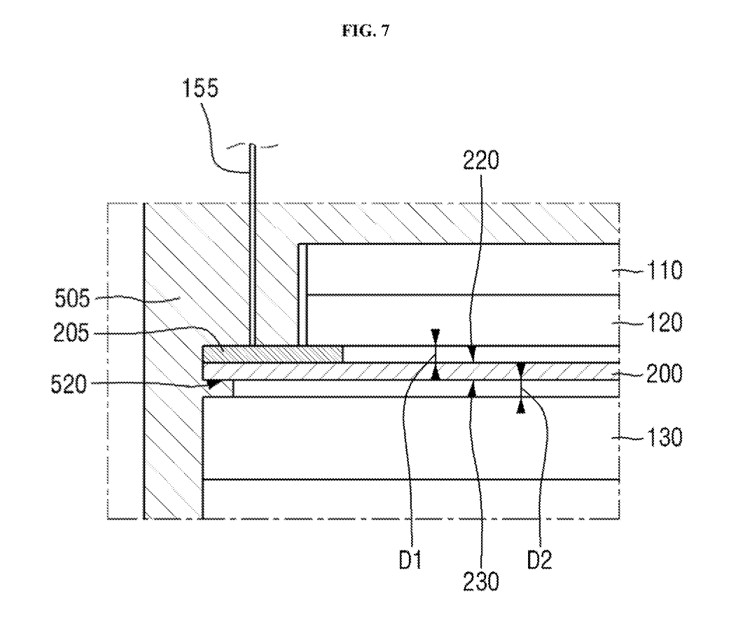

FIG. 7 is a conceptual diagram of a plasma treatment apparatus according to exemplary embodiments of the present invention.

Referring to FIG. 7, the plasma treatment apparatus, according to exemplary embodiments of the present invention, might not include a second metal ring 210 contacting a lower plate 130, unlike in the above-described configurations.

For example, an antenna 200 may contact a sidewall 505 of a plasma chamber 100, not through the second metal ring 210, but through a step 520 formed on the side wall 505.

The step 520 formed on the sidewall 505 may be disposed between the lower plate 130 and the antenna 200 to separate a second inner circumferential portion 230 of the antenna 200 from the lower plate 130.

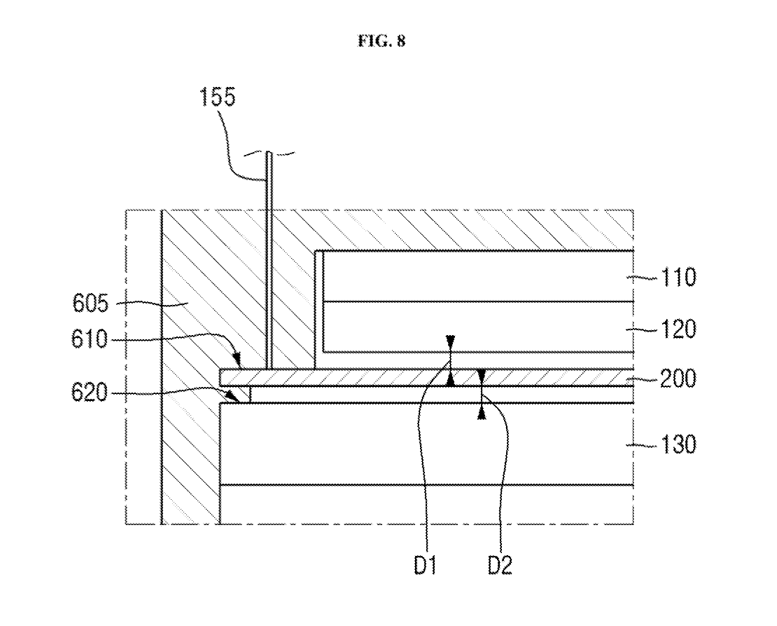

FIG. 8 is a conceptual diagram illustrating a plasma treatment apparatus according to exemplary embodiments of the present invention.

The plasma apparatus, according to exemplary embodiments of the present invention, might not include a first metal ring 205 and a second metal ring 210 contacting an upper plate 120 and a lower plate 130, respectively, unlike in the above-described configurations.

For example, an antenna 200 may contact a sidewall 605 through a step 610 formed on the sidewall 605. Therefore, a first inner circumferential portion 220 of the antenna 200 may be separated from the upper plate 120.

In addition, the antenna 200 may contact the sidewall 605 through a step 620 formed on the sidewall 605. Thus, a second inner circumferential portion 230 of the antenna 200 may be separated from the lower plate 130.

Exemplary embodiments described herein are illustrative, and many variations can be introduced without departing from the spirit of the disclosure or from the scope of the appended claims. For example, elements and/or features of different exemplary embodiments may be combined with each other.

What is claimed is:

1. A plasma treatment apparatus, comprising:
a plasma chamber configured to perform plasma treatment;
an upper plate disposed in an upper part of the plasma chamber;
an antenna disposed under the upper plate;
a lower plate disposed under the antenna;
a first metal ring attached to a first surface of the antenna and separating at least a portion of the first surface of the antenna from the upper plate; and
a second metal ring attached to a second surface of the antenna and separating at least a portion of the second surface of the antenna from the lower plate,
wherein a coolant path, that is configured to pass coolant therethrough, is formed in the antenna.

2. The apparatus of claim 1, wherein the antenna comprises:
a first inner circumferential portion defined on an inner side of the first surface; and
a first outer circumferential portion surrounding the first inner circumferential portion,
wherein the first outer circumferential portion is concentric with the first inner circumferential portion, and
wherein the first metal ring contacts the first outer circumferential portion.

3. The apparatus of claim 2, wherein the first inner circumferential portion is separated from the upper plate by the first metal ring and by a first distance.

4. The apparatus of claim 3, wherein the first distance is 0.1 mm to 5 mm.

5. The apparatus of claim 2, wherein the first inner circumferential portion comprises:
a first area in which a plurality of first slot holes penetrating the antenna are formed; and
a second area surrounding an outer circumference of the first area and in which a plurality of second slot holes penetrating the antenna are formed.

6. The apparatus of claim 5, wherein the coolant path passes through the first area and the second area.

7. The apparatus of claim 1, wherein the antenna comprises:
a second inner circumferential portion defined on an inner side of the second surface; and
a second outer circumferential portion surrounding the second inner circumferential portion,
wherein the second outer circumferential portion is concentric with the second inner circumferential portion, and
wherein the second metal ring contacts the second outer circumferential portion.

8. The apparatus of claim 7, wherein the second inner circumferential portion is separated from the lower plate by the second metal ring and by a second distance.

9. The apparatus of claim 8, wherein the second distance is 0.1 mm to 5 mm.

10. The apparatus of claim 9, wherein a contact surface between the coolant and the coolant path comprises a same material as the first surface of the antenna.

11. The apparatus of claim 1, wherein the antenna comprises an Invar alloy and/or a Kovar alloy.

12. The apparatus of claim 1, wherein the plasma chamber comprises a coolant supply path penetrating the plasma chamber to transport a coolant to the antenna, and the first metal ring comprises a through hole connected to the coolant supply path.

13. A plasma treatment apparatus, comprising:
a plasma chamber configured to perform a plasma treatment;
an upper plate disposed in an upper part of the plasma chamber;
a lower plate disposed under the upper plate; and
an antenna disposed between the upper plate and the lower plate, wherein at least a first portion of the antenna is separated from the upper plate and at least a second portion of the antenna is separated from the lower plate,
wherein a coolant path is formed in the antenna, and an inner surface of the coolant path comprises a same material as an outer surface of the antenna.

14. The apparatus of claim 13, wherein a sidewall of the plasma chamber comprises a first step separating the antenna from the upper plate.

15. The apparatus of claim 14, wherein a surface of the antenna comprises:
an outer circumferential portion overlapping the first step; and
an inner circumferential portion separated from the upper plate by the first step.

16. The apparatus of claim 15, wherein the coolant path is formed entirely within the inner circumferential portion.

17. The apparatus of claim 13, wherein the sidewall of the plasma chamber comprises a second step separating the antenna from the lower plate.

18. A plasma treatment apparatus, comprising:
a plasma chamber configured to perform plasma treatment;
an upper plate disposed in an upper part of the plasma chamber;
a lower plate disposed under the upper plate; and
an antenna disposed between the upper plate and the lower plate,
wherein the antenna comprises:
a first inner circumferential portion defined in a first surface facing the upper plate, the first inner circumference being separated from the upper plate and a first outer circumferential portion which surrounds the first inner circumferential portion;
a second inner circumferential portion defined in a second surface facing the lower plate, the second inner circumferential portion separated from the lower plate and a second outer circumferential portion which surrounds the second inner circumferential portion; and
a coolant path is formed in the antenna so as not to overlap the first and second outer circumferential portions.

19. The apparatus of claim 18, wherein the first outer circumferential portion is connected to the upper plate by a metal ring attached to the first surface.

20. The apparatus of claim 18, wherein the second outer circumferential portion is connected to the lower plate by a metal ring attached to the second surface.
